(19) United States
(12) Patent Application Publication
(10) Pub. No.: US 2013/0306590 A1
(43) Pub. Date: Nov. 21, 2013

(54) Stable Cavity-Induced Two-Phase Heat Transfer in Silicon Microchannels

(71) Applicant: Auburn University, Auburn, AL (US)

(72) Inventors: Sushil H. Bhavnani, Auburn, AL (US); Daniel T. Pate, Auburn, AL (US); Rory J. Jones, Auburn, AL (US)

(73) Assignee: Auburn University, Auburn, AL (US)

(21) Appl. No.: 13/951,035

(22) Filed: Jul. 25, 2013

Related U.S. Application Data
(62) Division of application No. 12/130,483, filed on May 30, 2008.
(60) Provisional application No. 60/932,383, filed on May 31, 2007.

(51) Int. Cl. B81C 1/00

(52) U.S. Cl. CPC B81C 1/00523
USPC 216/2; 216/41

(57) ABSTRACT

The stable cavity-induced two-phase heat transfer in silicon microchannels mitigates the flow of instabilities associated with two-phase (liquid/vapor) flow in microchannels. This is accomplished by etching microscopic cavities in the base of each microchannel using photolithography techniques. Each cavity is used to promote controlled nucleation activity. The microchannels with cavities are able to be used in heat sinks to cool a variety of electronic components.

### CROSS-REFERENCE TO RELATED APPLICATIONS

This application claims the benefit of U.S. Provisional Patent Application Ser. No. 60/932,383, filed May 31, 2007 and entitled STABLE CAVITY-INDUCED TWO-PHASE HEAT TRANSFER IN SILICON MICROCHANNELS; which is hereby incorporated herein by reference in its entirety for all purposes.

### FIELD OF THE INVENTION

The present invention relates to the field of heat exchangers. More specifically, the present invention relates to the field of two-phase heat exchangers containing microchannels with cavities.

### BACKGROUND OF THE INVENTION

Heat sinks are well known in computing to cool down computing components such as microprocessors by removing the heat generated by the component. Some heat sinks utilize air or other gases to cool down the component, some heat sinks use a liquid and other heat sinks use a combination of both a gas and a liquid. Generally liquids provide a better cooling mechanism than gas-only heat sinks. Two-phase flow (liquid-vapor) affords even better thermal performance but has been plagued by the presence of instabilities in the flow.

### SUMMARY OF THE INVENTION

The stable cavity-induced two-phase heat transfer in silicon microchannels mitigates the flow of instabilities associated with two-phase (liquid/vapor) flow in microchannels. This is accomplished by etching microscopic cavities in the base of each microchannel using photolithography techniques. Each cavity is used to promote controlled nucleation activity. The microchannels with cavities are able to be used in heat sinks to cool a variety of electronic components.

In one aspect, a system for transferring heat comprises a microchannel for providing a pathway for a fluid/vapor combination and a plurality of cavities contained within the microchannel, the plurality of cavities for stabilizing a liquid/vapor combination flow. The microchannel is two-phase. The plurality of cavities each comprise a pyramidal shape with a square mouth. The plurality of cavities are equally spaced on the bottom of the microchannel. The microchannel comprises silicon.

In another aspect, a method of manufacturing a microchannel comprises patterning cavities on a rear side of the wafer, wherein the cavities are pyramidal-shaped cavities, etching channels in the wafer and etching plenums through the wafer. The method further comprises growing an oxide layer on a wafer. The method further comprises patterning a front side of the wafer. The method further comprises masking off the channels. The microchannel is two-phase. The microchannel comprises silicon.

In another aspect, a method of manufacturing a microchannel comprises growing an oxide layer on a wafer, patterning cavities on a rear side of the wafer, generating pyramidal-shaped cavities from the cavities using a direction etch, patterning a front side of the wafer, etching channels in the wafer, masking off the channels and etching plenums through the wafer. The microchannel is two-phase. The microchannel comprises silicon.

In yet another aspect, a microchannel comprises an inlet, an outlet, a pathway between the inlet and the outlet, the pathway for permitting transport of a liquid/vapor combination and a plurality of cavities contained within the pathway, the plurality of cavities configured for stabilizing a liquid/vapor combination flow. The microchannel is two-phase. The plurality of cavities each comprise a pyramidal shape with a square mouth. The plurality of cavities are equally spaced on the bottom of the microchannel. The microchannel comprises silicon.

In another aspect, a heat sink comprises a top plate, a bottom plate and a wafer containing a microchannel with a plurality of cavities, the wafer sandwiched between the top plate and the bottom plate. The microchannel is two-phase. The plurality of cavities each comprise a pyramidal shape with a square mouth. The plurality of cavities are equally spaced on the bottom of the microchannel. The microchannel comprises silicon.

### BRIEF DESCRIPTION OF THE DRAWINGS

FIG. 1 illustrates a cross-section view of the cavity-enhanced microchannel geometry of a heat sink.

FIG. 2 illustrates an exploded view of the layers that comprise the sandwich construction of a heat sink.

FIG. 3A illustrates an image of reentrant cavities.

FIG. 3B illustrates a rear view of arrays of cavities.

FIG. 4 illustrates temperature sensors in a multichannel test device.

FIG. 5A illustrates a rear view of a fabricated and bonded device.

FIG. 5B illustrates a front view of a fabricated and bonded device.

FIG. 6 illustrates a flowchart of a method of manufacturing a microchannel array with cavities.

### DETAILED DESCRIPTION OF THE PREFERRED EMBODIMENT

A method of and system for providing stable cavity-induced two-phase (liquid/vapor) heat transfer in silicon microchannels is described. The method and system are accomplished by etching microscopic cavities in the base of each microchannel using photolithography techniques.

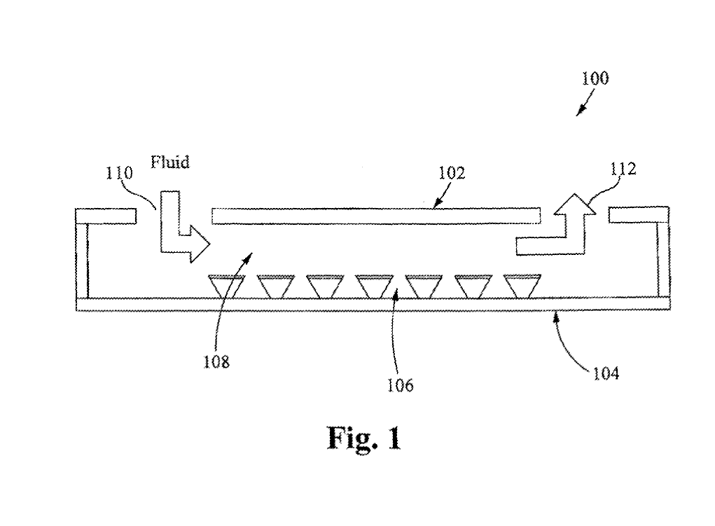

A heat sink includes one or more arrays of parallel microchannels. Re-entrant type cavities are located in the base of each channel, spaced equally along the length of the channel. The cavities are pyramidal in shape and have square mouths. A cross-section view of the cavity-enhanced microchannel geometry of a heat sink 100 is shown in FIG. 1. The heat sink 100 includes a top cover plate 102, a bottom plate 104, cavities 106 and a microchannel 108 with an inlet 110 and an outlet 112. In some embodiments, the top cover plate 102 and the bottom plate 104 comprise the same material such as Pyrex® or another material. The inlet 110 and outlet 112 are positioned so that fluid is able to enter and pass through and then out of the microchannel 108 and the cavities 106 for cooling purposes.

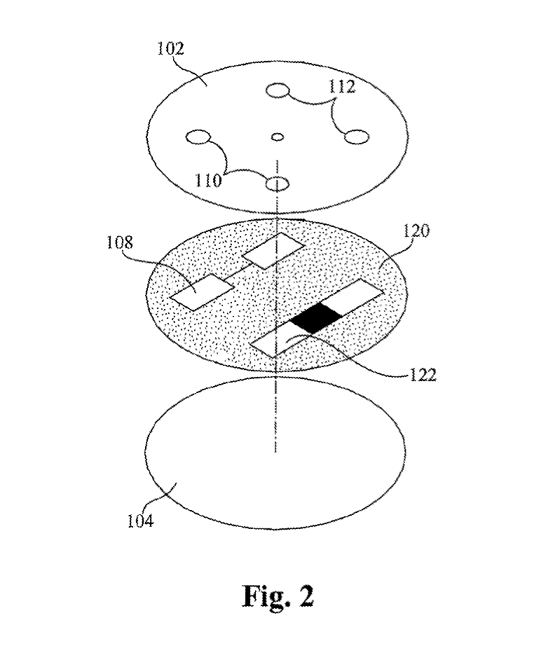

FIG. 2 illustrates an exploded view of the layers that comprise the sandwich construction of a heat sink. The top cover plate 102 includes a pair of inlets 110 and a pair of outlets 112. The channel plate 120 includes a single microchannel 108 and a multi-channel array 122. In some embodiments, the single microchannel 108 and the multi-channel array 122 comprise silicon. Isolation trenches, or air gaps, are etched on both sides of the microchannel array to reduce thermal spreading to the silicon. In some embodiments, the microchannel 108 and multi-channel array 122 comprise another material. In some embodiments, the top cover plate 102, the channel plate 120 and the bottom plate 104 are coupled together using anodic boding.

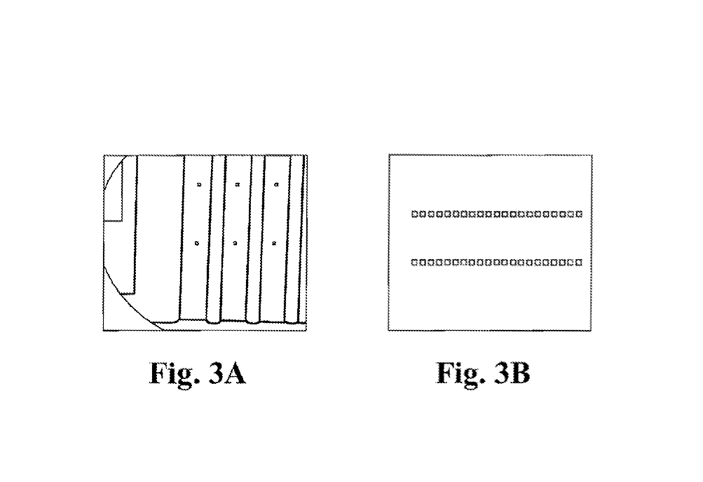

In some embodiments, the silicon microchannels are fabricated using 100 mm, double side polished, n-type silicon with a crystal orientation of <100>according to the cubic lattice system. In the cubic lattice system, the direction <hkl>defines a vector direction normal to the surface of a particular plane or facet, where h, k and l are Miller indices. In some embodiments, a 0.8 μm thick layer of oxide is grown on the wafer for etching buffer and general surface protection. Using photolithography and Buffered Oxide Etch (BOE), the cavities are patterned into the rear side of the wafer. Using the oxide layer as a mask, Tetra Methyl Ammonium Hydroxide (TMAH), a direction etch based on the orientation of the silicon, is used to generate the pyramidal-shaped cavities. The results of the etch are shown in FIGS. 3A and 3B which show a multi-channel device that has two cavities per channel.

In some embodiments, after the cavities are etched, photolithography and a BOE are used to pattern a series of shallow trenches on the topside of the wafer. In some embodiments, the wafer is placed in a Deep Reactive Ion Etcher (DRIE) where a 5 μm etch is conducted.

The upper surface of the silicon is patterned in preparation for etching the microchannels along with the inlet and outlet plenums. Once this is complete, the wafer is placed back inside the DRIE where the channels are etched to a desired depth. Once the peaks of the cavities are breached, an iterative process of measuring cavity opening size and returning the wafer to the DRIE continues until the square cavity openings fall within the desired tolerance as shown in FIG. 3A. At this point, the channel array is masked off and the wafer is placed in the DRIE for the etching of the plenums through the entire wafer thickness.

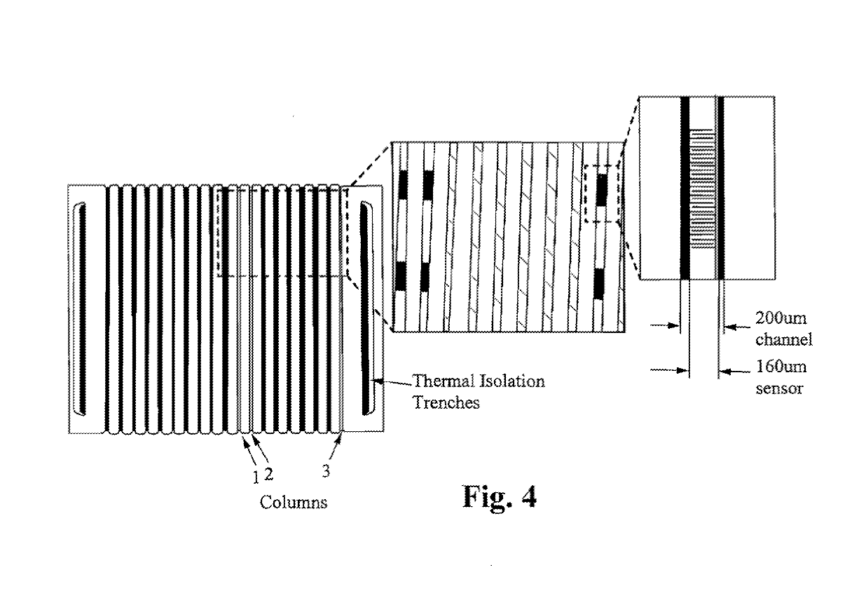

In general, obtaining true local fluid or surface temperatures from microchannels is able to be a daunting feat due to small feature sizes involved in the task. In some embodiments, sensors such as microthermometers are included in the heat sink below the top cover. The ability to use sensors on the inside surface and in contact with the flow is made possible by the dielectric properties of the working fluid FC72. In some embodiments, the multi-channel test devices contain twelve sensors each. The sensors are split into three groups of four, meaning that four sensors are aligned in series in the flow direction and spaced evenly along the length of three specific channels. FIG. 4 illustrates the layout of the sensor configuration and dimensions for a multi-channel device.

In some embodiments, the platform for the temperature sensor fabrication is a 5-inch piece of Pyrex® 7740 measuring 0.5 mm thick. This is achieved by photolithographic procedures used to pattern the 10 μm serpentine sensors onto the Pyrex® surface. Next, a 0.4 μm thick layer of pure aluminum is sputtered onto the surface and a standard lift-off procedure is performed leaving the sensors and contact pads. This top Pyrex® cover plate is additionally outfitted with four holes for the inlet and outlet flow ports.

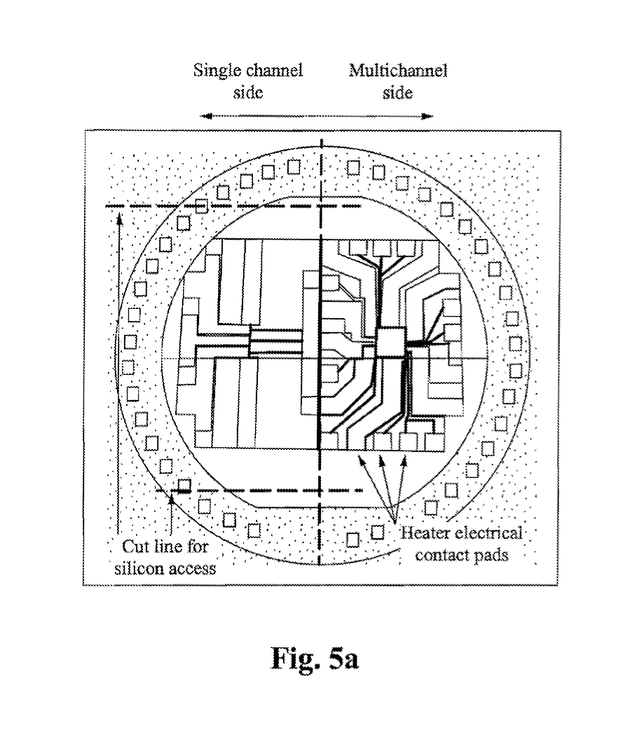

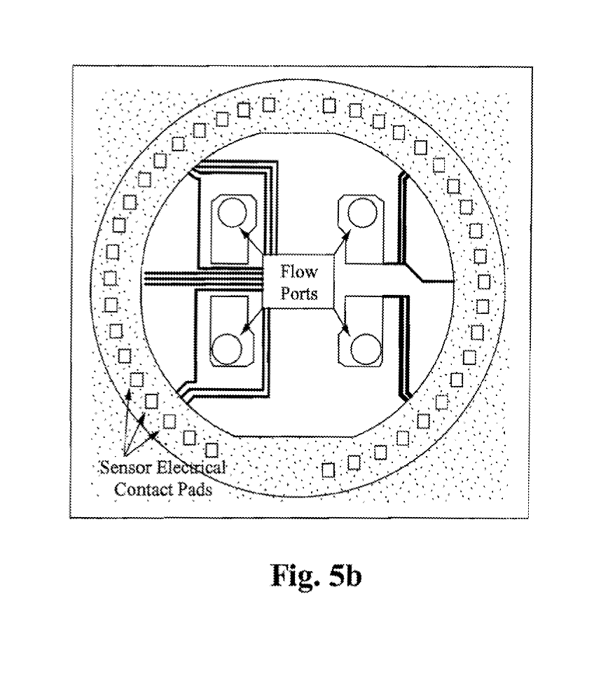

By etching a series of shallow trenches into the silicon, the sensors are able to be placed inside the channel to receive a signal for analysis. In some embodiments, since the sensors are only 0.4 μm thick, this gives considerable clearance for the sensor leads to exit the wafer and does not cause any interference with the bonding process. The heaters used to simulate heat-generating electronics are fabricated on a 4-inch piece of Pyrex® 7740, 0.5 mm thick, in some embodiments. This is achieved by first sputtering a 1 um layer of pure aluminum onto the Pyrex®. Standard photolithographic procedures are used to pattern the serpentine heaters and contact pads onto the backside of the glass. The aluminum was etched using a PAE (Phosphoric Aluminum Etch) solution. Once the heaters are fabricated, a thin slice is cut off of each side of the wafer as seen at the top and bottom of FIG. 5A using a dicing saw to allow access to the silicon during the bonding process. The bonding portion is a critical stage of fabrication. Bonding the two Pyrex® pieces to either side of the silicon generates the sandwich structure shown in FIG. 2. The configuration serves several major functions. The first is to seal the channels from the top and allow for channel flow. The second is to seal the cavities from the bottom. The third is that since the silicon is etched all the way through on the inlet and outlet plenum areas, the bond serves to seal those regions from the top and bottom.

Bonding the wafer begins by heating the set up to 350° C. which causes the Na+ ions in the glass to mobilize. Once this state is achieved, a voltage of 650V is applied instantaneously. The applied voltage drives the Na+ ions toward the negatively charged cathode. This migration of sodium away from the silicon to glass interface induced by the applied voltage causes a large bonding force between the two interfaces. A product of the bonding action is a visual measure of fringe lines in the glass. The fringe lines propagate away from the bonding area and continue doing so until the entire surface is bonded. The temperature and voltage are maintained for approximately three minutes or until the fringe lines have ceased to move. Once the bond is complete the voltage is cut off and the sandwich is allowed to cool slowly. After the bonding procedure is complete, the sandwich is able to be sawed in half as shown by the cut lines in FIG. 5A, separating the single channel wafer from the multi-channel wafer.

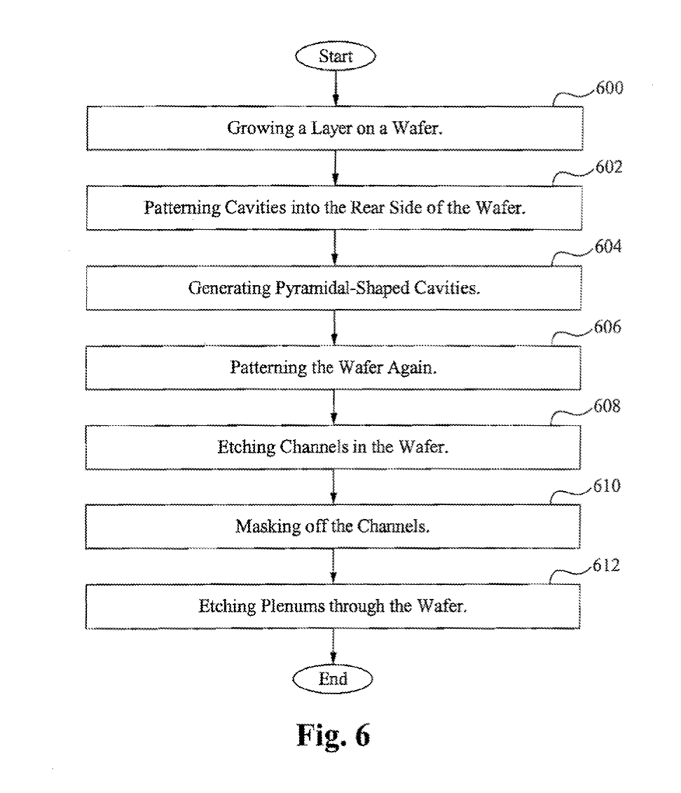

FIG. 5B illustrates the front surface of the fabricated and bonded device. Shown are the flow ports, two on the single microchannel side and two on the multi-channel side. FIG. 6 illustrates a flowchart of a method of manufacturing a microchannel array with cavities. The microchannel is able to be fabricated using a 100-mm, double side polished, n-type silicon with a crystal orientation of <100>as described above. In the step 600, a 0.8 μm thick layer of oxide is grown on the wafer for etching buffer and general surface protection. In the step 602, using photolithography and BOE, cavities are patterned into the rear side of the wafer. In the step 604, using TMAH, a direction etch based on the orientation of the silicon is used to generate the pyramidal-shaped cavities. In the step 606, the silicon is patterned again on the opposing side in preparation for etching of the channels along with the inlet and outlet plenums.

Then, in the step 608, the wafer is placed in a DRIE where the channels in a channel array are etched so as to breach the peaks of the cavities below to form a square cavity opening held to a tolerance of 20 μm ±4.5. In the step 610, the channel array is masked off. The wafer is then placed in the DRIE a second time to etch the plenums through the silicon completely, in the step 612.

To utilize the microchannels with cavities, the microchannels are incorporated in a heat sink or another device which is used to cool an electronic component. A liquid-gas (two-phase) is pumped through the microchannels with cavities to cool the electronic component so that the component does not overheat while generating heat when performing tasks such as computations. When incorporated in a heat sink, the heat sink is used similarly to other heat sinks, by placing the heat sink on the component to be cooled such as a microprocessor. By the liquid-gas traveling through the microchannels with cavities, the heat sink automatically helps cool the component down.

In operation, the method and system are able to be used with/as a heat sink to cool a variety of electronic products such as, but not limited to personal computers, servers, laptops, gaming systems, handheld devices, mobile phones and other devices. The microchannels with cavities are able to be integrated into the backside of a silicon microprocessor chip or into a heat sink/spreader. The geometric proportions are able to be scaled to the heat load of each specific application. The advanced two-phase cooling provides much better cooling than currently used air-cooling methodologies used in heat sinks.

The present invention has been described in terms of specific embodiments incorporating details to facilitate the understanding of principles of construction and operation of the invention. Such reference herein to specific embodiments and details thereof is not intended to limit the scope of the claims appended hereto. It will be readily apparent to one skilled in the art that other various modifications may be made in the embodiment chosen for illustration without departing from the spirit and scope of the invention as defined by the claims.

1.-5. (canceled)

6. A method of manufacturing a microchannel, the method comprising:
a. patterning cavities on a rear side of the wafer, wherein the cavities are pyramidal-shaped cavities;
b. etching channels in the wafer; and
c. etching plenums through the wafer.

7. The method of claim 6 further comprising growing an oxide layer on a wafer.

8. The method of claim 6 further comprising, patterning a front side of the wafer.

9. The method of claim 6 further comprising masking off the channels.

10. The method of claim 6 wherein the microchannel is two-phase.

11. The method of claim 6 wherein the microchannel comprises silicon.

12. A method of Manufacturing a microchannel, the method comprising:
a. growing an oxide layer on a wafer;
b. patterning cavities on a rear side of the wafer;
c. generating pyramidal-shaped cavities from the cavities using a direction etch;
d. patterning a front side of the wafer;
e. etching channels in the wafer;
f. masking off the channels; and
g. etching plenums through the wafer.

13. The method of claim 12 wherein the microchannel is two-phase.

14. The method of claim 12. wherein the microchannel comprises

15.-24. (canceled)
